(19) United States
(12) Patent Application Publication
(10) Pub. No.: US 2018/0335802 A1
(43) Pub. Date: Nov. 22, 2018

(54) MOBILE COMPUTING DEVICE PROTECTOR

(71) Applicant: Mobile Tech, Inc., Lake Oswego, OR (US)

(72) Inventors: Eric Charlesworth, Hillsboro, OR (US); Peter Schuft, Hillsboro, OR (US)

(21) Appl. No.: 15/866,250

(22) Filed: Jan. 9, 2018

Related U.S. Application Data
(63) Continuation-in-part of application No. 15/600,642, filed on May 19, 2017.

(51) Int. Cl. G06F 1/16; H04B 1/3888; H05K 5/03

(52) U.S. Cl. CPC G06F 1/1626; A45C 2011/002; H05K 5/03; H04B 1/3888

(57) ABSTRACT

A system capable of protecting at least a portion of the computing device may comprise a liner substantially comprising an elastic material having predetermined Shore durometer measurement. The liner may fit adjacent to a non-display side of a mobile computing device. The system may further comprise a bezel capable of fitting around at least a portion of a perimeter of the display side of a mobile computing device.

### CROSS-REFERENCE TO RELATED APPLICATIONS

This application is a continuation-in-part of U.S. patent application Ser. No. 15/600,642, filed May 19, 2017, which is incorporated herein by reference.

### BACKGROUND

### 1. Field

This disclosure relates generally to covers and/or enclosures to protect particular types of mobile devices during their operation and/or use.

### 2. Information

As mobile computing devices continue to increase in capability and functionality, for example, deployment of mobile computing devices in offices, hospitals, industrial settings, and other types of environments, also continues to increase. In some instances, to assist in obtaining and/or maintaining an advantage over competitors, a business may place a premium on obtaining the most capable and/or most up-to-date mobile computing devices as soon as those devices become available. However, although many types of mobile computing devices, such as tablet computing devices, for example, continue to decrease in price, purchasing a number of mobile computing devices for a particular business environment may nonetheless represent a significant investment. Accordingly, for this reason, and potentially others, it may be advantageous to ensure that newly-acquired mobile computing devices are protected from damage, such as damage brought about by dropping a mobile computing device, spilling liquids on a mobile device, operating a mobile computing device in a dusty environment, and so forth.

However, particular mobile computing devices, such as tablet computing devices, for example, may be released to a market prior to development of suitable protective devices. Thus, after the purchase of, for example, a quantity of mobile computing devices for particular business applications, such as for use in hospital environments, industrial environments, and so forth, a business may refrain from deploying mobile devices until suitable protective covers and/or enclosures can be obtained. In other instances, a business may simply deploy newly-acquired mobile computing devices without protective coverings, for example, in hopes that the devices experience only minimal wear and tear until protective measures can be obtained.

### BRIEF DESCRIPTION OF THE DRAWINGS

Claimed subject matter is particularly pointed out and/or distinctly claimed in the concluding portion of the specification. However, both as to organization and/or method of operation, together with objects, features, and/or advantages thereof, claimed subject matter may be understood by reference to the following detailed description if read with the accompanying drawings in which:

FIG. 1 is a perspective view of a tablet computing device situated within a mobile computing device protector, according to an embodiment.

FIG. 2 is a perspective view of the mobile computing device protector shown in FIG. 1, wherein particular features of the mobile computing device protector are shown, according to an embodiment.

FIG. 3 is a perspective view showing of components of the mobile computing device protector shown in FIGS. 1 and 2, according to an embodiment.

FIG. 4 is a view showing a front portion of a liner of the mobile computing device protector shown in FIG. 3, according to an embodiment.

FIG. 5 is a perspective view showing a rear portion of the liner of the mobile computing device protector of FIG. 4, according to an embodiment.

FIG. 6 is a front perspective view showing an embodiment of a bezel of the tablet case assembly.

FIG. 7 is a rear perspective view of the bezel shown in FIG. 6.

FIG. 8 is a front perspective view showing an embodiment of a liner of the tablet case assembly.

FIG. 9 is a rear perspective view of the liner shown in FIG. 7.

FIG. 10 is a rear perspective view of an embodiment of the back portion of the tablet case assembly.

FIG. 11 is a front perspective view of the embodiment of the back portion shown in FIG. 10.

In the following detailed description, reference is made to accompanying drawings, which form a part of the detailed description, wherein like numerals may designate like parts throughout the figures to indicate corresponding and/or analogous components. It will be appreciated that components illustrated in the figures have not necessarily been drawn to scale, such as for simplicity and/or clarity of illustration. For example, dimensions of some components may be exaggerated relative to other components. Further, it is to be understood that other embodiments may be utilized. Furthermore, structural and/or other changes may be made without departing from the scope of claimed subject matter.

### DETAILED DESCRIPTION

Reference throughout this specification to “one example,” “one feature,” “one embodiment,” “an example,” “a feature,” “an implementation,” or “an embodiment” means that a particular feature, structure, or characteristic described in connection with the feature, example, or embodiment is included in at least one feature, example, or embodiment of claimed subject matter. Thus, appearances of the phrase “in one example,” “an example,” “in one implementation,” “an implementation,” “an embodiment,” or “in one embodiment” in various places throughout this specification are not necessarily all referring to the same feature, example, or embodiment. Particular features, structures, or characteristics may be combined in one or more examples, features, or embodiments.

As mentioned previously herein, certain businesses may place a premium on obtaining the most capable and/or most up-to-date mobile computing devices immediately after the mobile computing devices become available. As used herein, “mobile device,” “mobile communication device,” “mobile computing device,” or like terms may be used interchangeably and may refer to any kind of special purpose computing platform or apparatus that may from time to time occupy a position or location that changes. In some instances, a mobile communication device may, for example, be capable of communicating with other devices, mobile or otherwise, through wireless transmission and/or receipt of information according to one or more communication protocols. As a way of illustration, special purpose mobile communication devices, which may herein be called simply mobile devices, may include, for example, cellular telephones, smart telephones, personal digital assistants (PDAs), laptop computers, personal entertainment systems, tablet personal computers (PC), tablet computing devices, personal audio and/or video devices, personal navigation devices, or the like. It should be appreciated, however, that these are merely examples of mobile devices that may be used, at least in part, herein, and that claimed subject matter is not limited in this regard.

However, although many types of mobile computing devices, such as tablet computing devices, for example, continue to decrease in cost, purchasing a number of capable and/or feature-rich mobile computing devices may nonetheless represent a significant monetary investment. Accordingly, particularly for use within environments in which mobile computing devices are to be moved from place to place, such as in hospital environments, industrial environments, and so forth, it may be advantageous to ensure that mobile computing devices are protected within a case or other type of protective enclosure. However, on occasions, when mobile computing devices are introduced into a market, these devices may not be provided with adequate protective coverings, which may operate to protect a mobile computing device from shock, vibration, exposure to liquids and/or harsh chemicals, for example. Thus, a business or other entity that may have secured one or more mobile computing devices for deployment may be required to wait for perhaps several weeks or longer, for example, until suitable protective coverings can be manufactured and made available. Alternatively, rather than waiting for suitable protective coverings to become available, a business or other entity may simply decide to utilize newly-acquired mobile computing devices, even though such devices may be susceptible to damage and/or undue wear and tear.

In addition, it may be desirable for a protective covering of a mobile computing device to be compatible with portable and/or universal docking stations. For example, in a hospital setting, portable docking stations may be located at a number of locations throughout the hospital. Accordingly, at times, hospital personnel may wish to dock a mobile computing device at any locally available portable and/or “universal” docking stations, which may permit the mobile computing device to charge, receive and transmit parameters securely via a wired interface, receive updates via a wired interface, and so forth.

However, embodiments of claimed subject matter may represent an approach toward providing protective measures for mobile computing devices. Such measures may be made available in a more timely manner than previously possible and without requiring specialized, hardened metal tooling. In particular embodiments, approaches toward providing protective measures for mobile computing devices may involve design and manufacture of a single customized component, such as a mobile computing device protective liner, for example. In embodiments, a protective liner may be attached to a mobile computing device and attached to one or more non-customized components, such as components capable of being utilized across an entire family or size category of mobile computing products. In particular embodiments, such a combination of customized and non-customized components may comprise a complete protection solution for a mobile computing device. In addition, a complete protection solution may additionally provide interchangeability with universal docking stations, which may permit differently-sized mobile computing devices (e.g., 8-inch, 10-inch, 12-inch, and so forth) to be charged, updated, and/or to engage in secure communications, for example. Along these lines, at least some claimed subject matter may be directed to a protective, elastic liner meant adapt any mobile computing device within a particular size category (such as 8-inch, 10-inch, 12-inch, and so forth) to a universal docking station.

Thus, in particular embodiments, a mobile computing device protector may be formed from a customized component and one or more components utilized across, for example, families of nominally 8-inch, 10-inch, 12-inch, or other sized mobile computing devices. For example, as described herein, a mobile computing device protector may comprise a bezel, which may be placed at least partially in contact with a first side, which refers to a display side, of a mobile computing device. The bezel may be attached to a mobile computing device protector liner, which may be placed at least partially in contact with a second side (which refers to a non-display side of a mobile computing device), thereby retaining the mobile computing device between the liner and the bezel. A mobile computing device protector may additionally comprise a back portion, which may be utilized, at least in part, to fasten together the mobile computing device protector liner, bezel, and back portion so as to form a mobile computing device protector. As will be shown and described, embodiments, fastening of a back portion to a mobile computing device protective liner and bezel may additionally provide an approach toward mounting the mobile computing device to a universal docking station, for example. In particular embodiments, a back portion of a mobile computing device protector may comprise additional features, such as features to permit the mobile computing device protector to be secured to a hand and/or shoulder strap, for example. In embodiments, use of a hand and/or shoulder strap, may permit the mobile computing device to be carried from place to place with a reduced risk of being dropped, for example.

A protective liner may be manufactured from any suitable material, such as elastic material, for example, capable of facilitating and/or supporting one or more approaches and/or objectives discussed herein. For example, in at least one implementation, a mobile computing device protective liner may be manufactured from a moldable relatively elastic material, having a Shore durometer measurement of between 55.0 (A) and 85.0 (A). In other embodiments, an elastic material utilized to form a mobile computing device protective liner may comprise a Shore durometer measurement of between 70.0 (A) and 80.0 (A). In other embodiments, an elastic material utilized to form a mobile computing device protective liner may comprise a Shore barometer measurement of between 40.0 (A) and 95.0 (A) (or even as high as 100.0 (A), for example). However, claimed subject matter is intended to embrace protective liners comprising any predetermined Shore durometer measurement. Use of elastic materials having such Shore durometer measurements may operate as a cushion in the event that the mobile computing device is accidentally dropped, for example. In addition, an elastic protective liner may provide a relatively tight, snug, and/or secure fit around contours of mobile computing devices in a way that may mitigate or prevent exposure of surfaces of the mobile computing device to cleaning solvents, dust, chemicals, water, etc., which may permit the mobile computing device to operate relatively trouble-free for extended periods of time. In embodiments, liner 120 may comprise a thickness of between 1.0 mm and 3.0 mm, although claimed subject matter is not limited in this regard. In particular embodiments, liner 120 may comprise a front-to-back thickness of between 1.0 cm and 3.0 cm although, again, claimed subject matter is not limited in this respect. For example, in other embodiments, liner 120 may comprise a front-to-back thickness of 0.75 cm, for example, or may comprise a front-to-back thickness of 3.5 cm, or greater.

A mobile computing device protective liner may comprise a number of ribs, which may operate to further reduce likelihood of damage to the mobile computing device responsive to exposure to shock and/or vibration, for example. In addition, a mobile computing device protector may provide features such as holes and/or cutouts to accommodate, for example, a mobile computing device camera. Further, one or more vents may be situated in a mobile computing device protective liner to correspond with locations at which fans and/or other heat dissipation measures are located on a particular mobile computing device. In embodiments, a mobile computing device protective liner may provide one or more recesses, within which one or more membranes may be located wherein the membranes correspond to locations at which switches are positioned on a particular type of mobile computing device. A mobile computing device protective liner may additionally incorporate a cable race, for example, to accommodate a cable utilized for charging of the mobile computing device, for example, without removing the mobile computing device from a device protector.

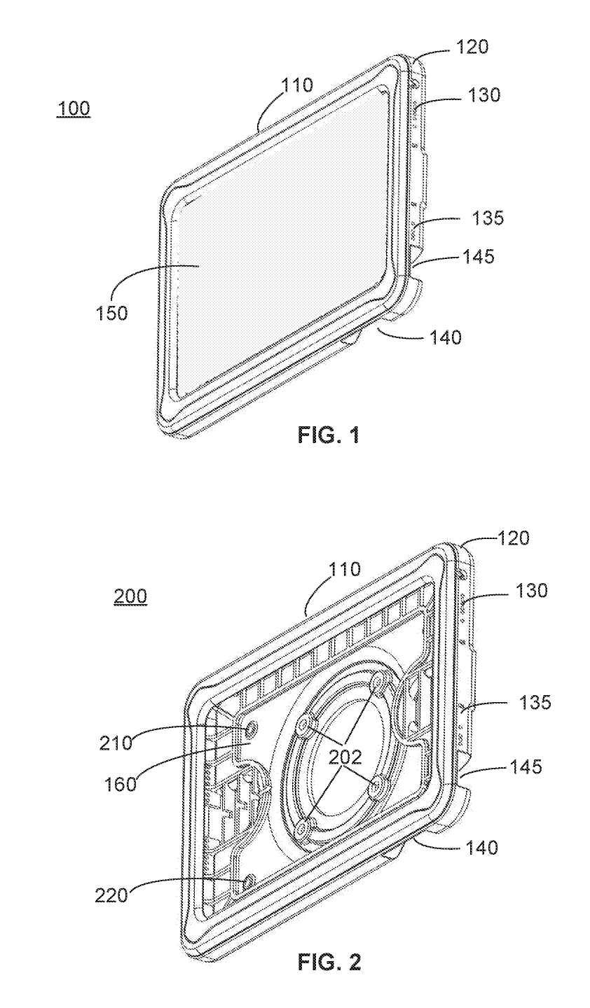

FIG. 1 is a perspective view of a tablet computing device 150 situated within a mobile computing device protector, according to an embodiment 100. Bezel 110 is shown in FIG. 1 as surrounding, such as at a perimeter portion of a display of tablet computing device 150. However, in particular embodiments, bezel 110 may surround only a portion of a display of tablet computing device 150, and claimed subject matter is not limited in this respect. In addition, although bezel 110 is shown in FIG. 1 as not encroaching upon and/or covering the display of tablet computing device 150, in particular embodiments may include a bezel that encroaches and/or covers some portion of a display of tablet computing device 150, for example.

Mobile computing device cover protective liner 120, which may be referred to as “liner” 120, may be coupled and/or connected to bezel 110 in a manner that tightly and/or snugly envelops tablet computing device 150. As shown in FIG. 1, protective liner 120 may incorporate vents 130 and 135 which may, for example, correspond to the vents located on tablet computing device 150. Accordingly, via positioning of the vents 130 and 135, for example, heat dissipation, airflow and/or other parameters of tablet computing device 150 may be maintained or only minimally impacted. Liner 120 may additionally comprise recesses 140 and 150 which may correspond to locations at which selector buttons, volume controls, etc. may be situated on a surface of tablet computing device 150.

FIG. 2 is a perspective view of the mobile computing device cover of FIG. 1, showing particular features according to an embodiment 200. In FIG. 2, with tablet computing device 150 removed, additional features of liner 120 as well as mobile computing device protector back portion 160 (referred to as back portion 160) may also be viewed. Accordingly, mobile computing device back portion 160 shows four screw holes 202, which may provide compatibility with VESA (Video Electronics Standards Association) mounting brackets. However, in other embodiments, screw holes 202 may be fewer in number, such as including three or fewer screw holes, or may be greater in number, such as including five or greater screw holes, and claimed subject matter is not limited in this respect. Mobile computing device back portion 160 may additionally include screw holes 210 and 220 which may, for example, accommodate a hand and/or shoulder strap, for example, D-ring fasteners, and so forth, which may permit a tablet computing device to be carried from place to place.

In addition to providing compatibility of back portion 160 with VESA mounting brackets, back portion 160 may additionally be compatible and/or interchangeable with a number of portable docking stations, which may be available throughout a hospital, industrial facility, and so forth. In embodiments, back portion 160 may provide a capability to mount a number of differently-sized mobile computing devices to a portable docking station. For example, back portion 160 may permit an 8-inch mobile computing device, 10-inch mobile computing device, 12-inch mobile computing device, and/or differently-sized mobile computing device to be physically connected with a single, universal portable docking station. Accordingly, a single, universal portable docking station may be utilized to charge and/or facilitate updates to an 8-inch mobile computing device, a 10-inch mobile computing device, and a 12-inch mobile computing device, (but not simultaneously) within a single business day.

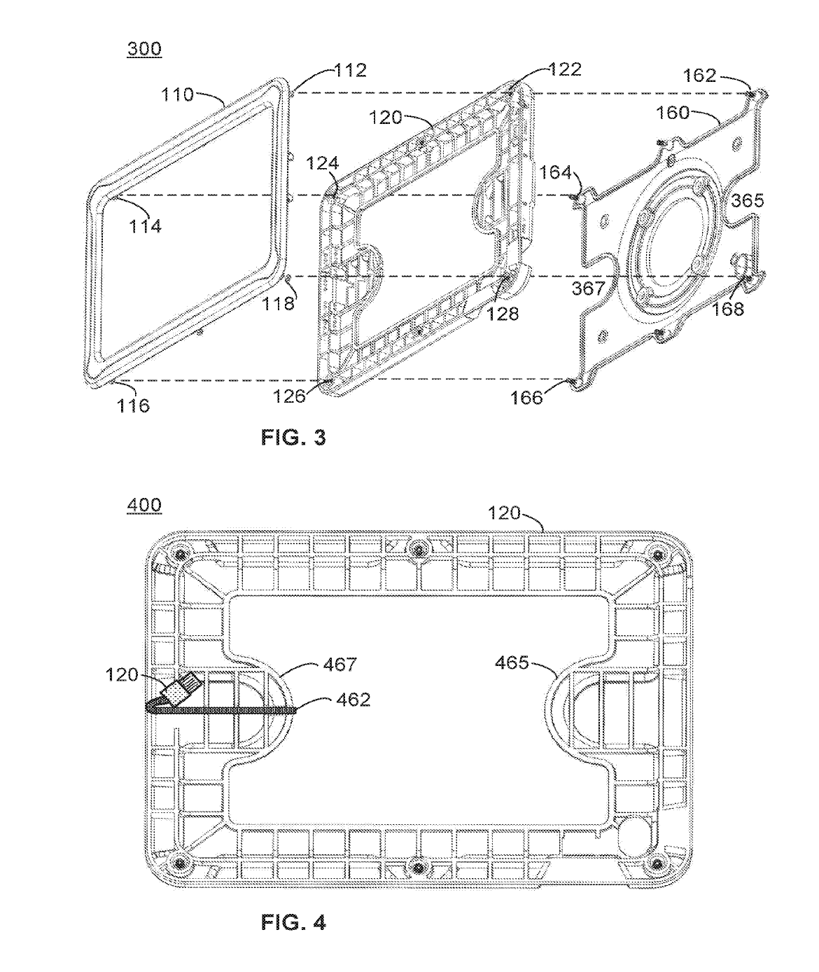

FIG. 3 is a perspective view showing of components of the mobile computing device cover of FIGS. 1 and 2 according to an embodiment 300. In embodiments, the bezel 110 and mobile computing device back portion 160 may comprise a hard plastic and/or metallic material comprising sufficient to retain liner 120 and tablet computing device 150 between bezel 110 and back portion 160. As shown in FIG. 3, to assemble a mobile computing device protector, screw 162 of back portion 160 may be fit through screw hole 102 of liner 120 so as to mate with screw boss 112 of bezel 110. Similarly, screw 164 of back portion 160 may fit through screw hole 124 of liner 120 so as to mate with screw boss 114 of bezel 110. Likewise, screw 166 may fit through screw hole 126 so as to mate with screw boss 116. Further, screw 168 of back portion 160 may fit through screw hole 128 so as to mate with screw boss 118. It should be noted that assembly of bezel 110, liner 120, and back portion 160 may be accomplished by any number of additional approaches, perhaps using a larger or smaller number of screws, screw holes, and screw bosses, for example, and claimed subject matter is not limited in this respect. Mobile computing device back portion 160 may additionally comprise indents 365 and 367, which may align with features of liner 120, described with respect to FIG. 4.

FIG. 4 is a view showing a front portion of a liner of the mobile computing device cover shown in FIG. 3, according to an embodiment 400. In the embodiment of FIG. 4, protective liner 120 may comprise outcrops 466 and 467, which may mate with indents 365 and 367. In embodiments, outcrops 466, for example, may correspond to a location of a camera on a tablet computing device for example. In such an instance, outcrops 466 may be easily removed, or a mold utilized to form outcrops 466, for example, may be modified so as to be excluded from liner 120, thereby permitting visibility of a camera lens. Outcrop 467 may additionally comprise a cable race, which may permit a cable to be inlaid within liner 120. As previously mentioned, and ability for liner 120 to accommodate a cable, such as cable 462, may permit charging of a tablet computing device while operation within a mobile computing device cover, for example.

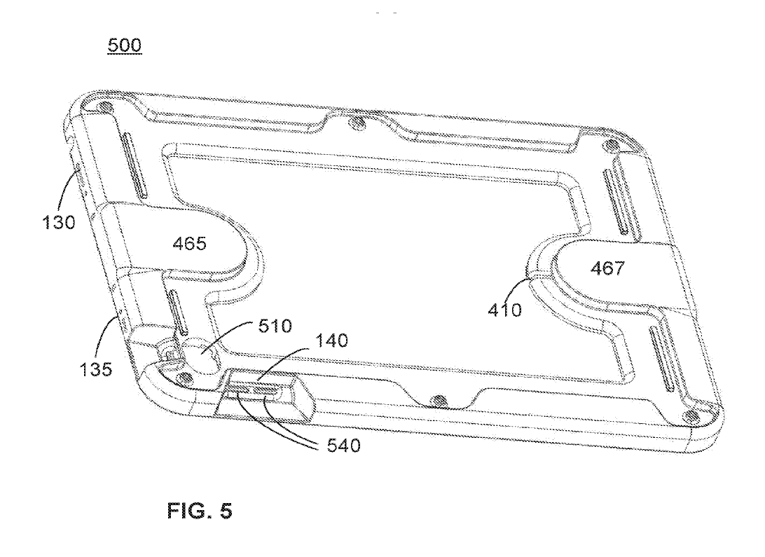

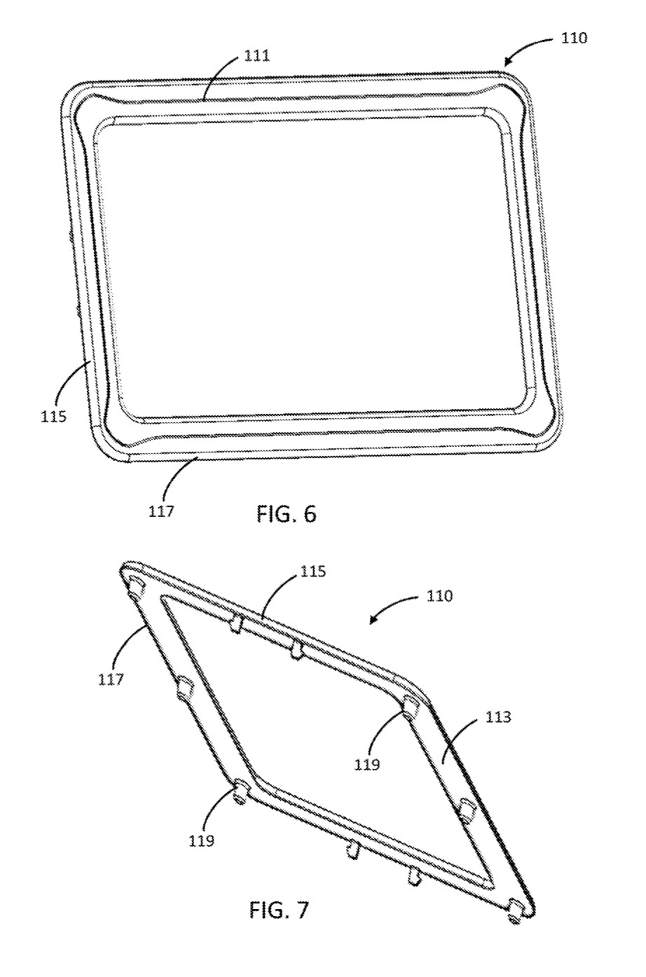

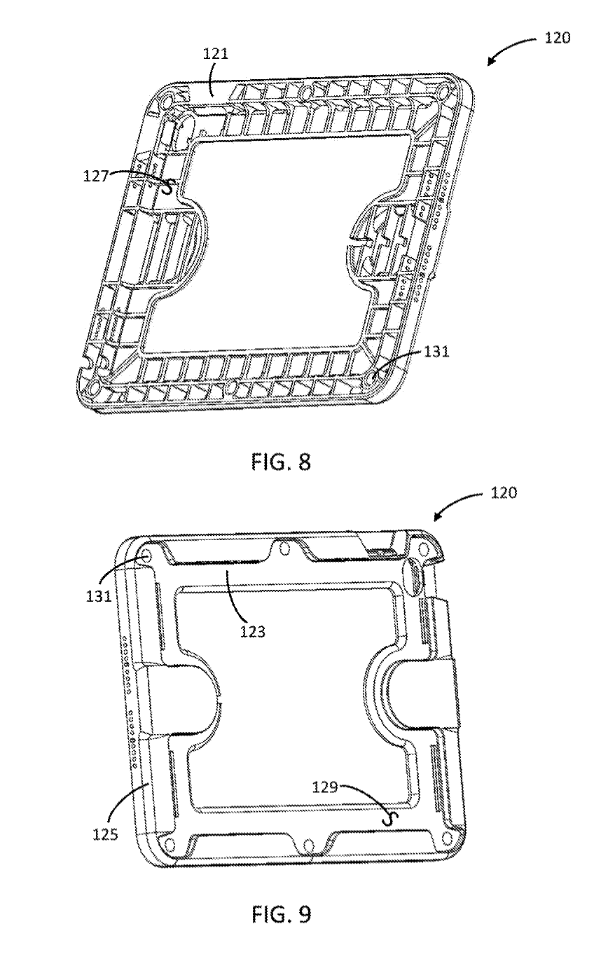

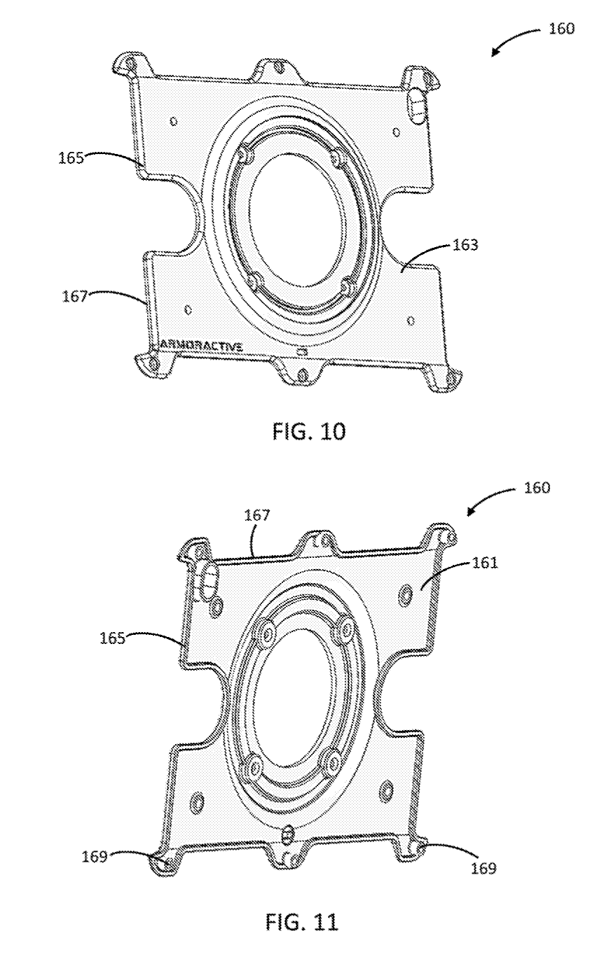

FIG. 5 is a perspective view showing a rear portion of a liner of the mobile computing device cover of FIG. 4, according to an embodiment 500. FIG. 5 illustrates an additional camera hole 510 along with the membranes 540, which may be positioned within recess 140. In embodiments, membranes 540 may comprise a thickness of, for example, 0.25 mm to 1.5 mm, thereby permitting a user to depress volume control buttons, selector switches, and/or perform other control functions on a tablet computing device while the tablet computing device is enclosed within a cover. In embodiments, membranes 540 may comprise a thickness so as to permit depression of a selector switch having an area of as little as 0.5 cm², however, claimed subject matter is not limited in this respect.

As discussed above, the case assembly includes the bezel 110, the liner 120 and the back portion 160. The bezel 160 includes a front bezel face 111, a rear bezel face 113, and an outer bezel periphery 115 extending from the front bezel face to the rear bezel face. The outer bezel periphery 115 includes a bezel edge 117. The liner 120 includes a front liner face 121, a rear liner face 123, and an outer liner periphery 125 extending from the front liner face to the rear liner face. The liner 120 further includes a front recess 127 located in the front liner face 121 for receiving an electronic tablet device and a rear recess 129 located in the rear liner face 123 for receiving the back portion 160. The rear recess 129 is shaped and configured to receive the back portion 160. The liner 120 is configured to circumscribe the outer tablet periphery when an electronic tablet device is located in the front recess 127. The back portion 160 includes a front back portion face 161, a rear back portion face 163, and an outer back portion periphery 165 extending from the front back portion face to the rear back portion face. The outer back portion periphery 165 including a back portion edge 167.

The bezel 110 further includes a plurality of bezel protrusions 119 extending from the rear bezel face 113. The back portion 160 furthers include a plurality of back portion protrusions 169 extending from the front back portion face 161. The liner 120 further includes a plurality of through-openings 131 extending from the front liner face 121 to the rear liner face 123. The through-openings 131 are configured to receive the back portion protrusions 169 and the bezel protrusions 119 when the case assembly is assembled.

The back portion 160, bezel 110 and liner 120 are configured such that the front back portion face 161 contacts the rear liner face 123 and the rear bezel face 113 contacts the front liner face 121 when the case assembly is assembled. The back portion edge 167 of the outer back portion periphery 165 is devoid of connection to the bezel edge 117 of the outer bezel periphery 115 when the tablet case assembly is assembled. Additionally, the back portion edge 167 of the outer back portion periphery 165 is spaced from the bezel edge 117 of the outer bezel periphery 115 when the tablet case assembly is assembled. The liner 120 is sandwiched between the back portion 160 and the bezel 110 when the case assembly is assembled. The bezel protrusions 119 and the back portion protrusions 169 are located within the through-openings 131 of the liner 120 when the case assembly is assembled.

In operation, a user places a first electronic tablet device in a recess of a first liner. The first electronic tablet device has a front tablet face, a rear tablet face and an outer tablet periphery extending from the front tablet face to the rear tablet face. The first liner has a first width, a first length and a first thickness. The recess of the first liner has a first shape for snugly receiving and accommodating the first electronic tablet device such that the first liner surrounds the outer tablet periphery of the first electronic tablet device. The user then attaches a bezel and a back portion to the first liner. The bezel contacts a front liner face of the first liner and the back portion contacts a back liner face of the first liner, thereby sandwiching the first liner between the bezel and the back portion. The back portion is connected to the bezel to secure the first liner between the back portion and the bezel.

The user may subsequently disconnect the back portion from the bezel and detach the back portion and the bezel from the first liner. The user may then place a second electronic tablet device in a recess of a second liner, and attach the bezel and the back portion to the second liner. The second electronic tablet device has a front tablet face, a rear tablet face and outer tablet periphery. The second liner has a second width, a second length and a second thickness. The second thickness of the second liner is different from the first thickness of the first liner. The second width of the second liner is substantially similar to the first width of the first liner. Likewise, the second length of the second liner is substantially similar to the first length of the first liner. The recess of the second liner has a second shape for snugly receiving and accommodating the second electronic tablet device such that the second liner surrounds the outer tablet periphery of the second electronic tablet device. The back portion may then be connected to the bezel to secure the second liner between the back portion and the bezel. Thus, as detailed above, the bezel and the back portion are capable of being attached to both the first liner and the second liner.

In the present patent application, terms such as “over” and “under” are understood in a similar manner as the terms “up,” “down,” “top,” “bottom,” “upward,” “downward,” and so on, as previously mentioned. These terms may be used to facilitate discussion, but are not intended to necessarily restrict scope of claimed subject matter. For example, the term “over,” as an example, is not meant to suggest that claim scope is limited to only situations in which an embodiment is right side up, such as in comparison with the embodiment being upside down, for example. Thus, if an object, as an example, is within applicable claim scope in a particular orientation, such as upside down, as one example, likewise, it is intended that the latter also be interpreted to be included within applicable claim scope in another orientation, such as right side up, again, as an example, and vice-versa, even if applicable literal claim language has the potential to be interpreted otherwise. Of course, again, as always has been the case in the specification of a patent application, particular context of description and/or usage provides helpful guidance regarding reasonable inferences to be drawn.

Unless otherwise indicated, in the context of the present patent application, the term “or” if used to associate a list, such as A, B, or C, is intended to mean A, B, and C, here used in the inclusive sense, as well as A, B, or C here used in the exclusive sense. With this understanding, “and” is used in the inclusive sense and intended to mean A, B, or C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Likewise, the term “based on” and/or similar terms are understood as not necessarily intending to convey an exhaustive list of factors, but to allow for existence of additional factors not necessarily expressly described.

While there has been illustrated and/or described what are presently considered to be example features, it will be understood by those skilled in the relevant art that various other modifications may be made and/or equivalents may be substituted, without departing from claimed subject matter. Additionally, many modifications may be made to adapt a particular situation to teachings of claimed subject matter without departing from the central concept(s) described herein. Therefore, it is intended that claimed subject matter not be limited to particular examples disclosed, but that such claimed subject matter may also include all aspects falling within appended claims and/or equivalents thereof.

What is claimed is:

1. A method comprising:
sandwiching a first liner between a back portion and a bezel, the first liner having a first shape to snugly receive and accommodate a first electronic tablet device;
connecting the back portion to the bezel to secure the first liner between the back portion and the bezel;
disconnecting the back portion from the bezel;
replacing the first liner with a second liner, the second liner having a second shape to receive and accommodate a second electronic tablet device, the second shape differing from the first shape;
sandwiching the second liner between the back portion and the bezel.

2. A method as set forth in claim 1 wherein the first liner has a first width, a first length and a first thickness, and wherein the second liner has a second width a second length and a second thickness, the first thickness being different from the second thickness.

3. A method as set forth in claim 2 wherein the first width is similar to the second width and the first length is similar to the second length.

4. A method comprising:
providing a first liner and a second liner, the first liner having a first shape for snugly receiving and accommodating a first electronic tablet device, the second liner having a second shape for receiving and accommodating a second electronic tablet device, the first shape differing from the second shape;
placing the first electronic tablet device in a recess of the first liner, the first electronic tablet device having a front tablet face, a rear tablet face and an outer tablet periphery extending from the front tablet face to the rear tablet face, the first liner surrounding the outer tablet periphery of the first electronic tablet device; and
attaching a bezel and a back portion to the first liner such that the bezel contacts a front liner face of the first liner and the back portion contacts a back liner face of the first liner, thereby sandwiching the first liner between the bezel and the back portion;
wherein the bezel and the back portion are capable of being serially attached to the first liner and the second liner.

5. A method as set forth in claim 4 wherein the method further comprises:
detaching the bezel and the back portion from the first liner;
placing the second electronic tablet device in a recess of the second liner, the second electronic tablet device having a front tablet face, a rear tablet face and an outer tablet periphery extending from the front tablet face to the rear tablet face, the second liner surrounding the outer tablet periphery of the second electronic tablet device; and
attaching the bezel and the back portion to the second liner such that the bezel contacts a front liner face of the second liner and the back portion contacts a back liner face of the second liner, thereby sandwiching the second liner between the bezel and the back portion.

6. A tablet case assembly for an electronic tablet device having a front tablet face, a rear tablet face and an outer tablet periphery extending from the front tablet face to the rear tablet face, the tablet case assembly comprising:
a bezel having a front bezel face, a rear bezel face and an outer bezel periphery extending from the front bezel face to the rear bezel face, the outer bezel periphery including a bezel edge;
a liner of an elastomeric material, the liner including a recess for receiving the electronic tablet device, the liner being configured to circumscribe the outer tablet periphery of the electronic tablet device when the electronic tablet device is located in the recess, the liner comprising a front liner face, a rear liner face and an outer liner periphery extending from the front liner face to the rear liner face;
a back portion having a front back portion face, a rear back portion face and an outer back portion periphery extending from the front back portion face to the rear back portion face, the outer back portion periphery including a back portion edge;
wherein the back portion, bezel and liner are configured such that the front back portion face contacts the rear liner face and the rear bezel face contacts the front liner face when the tablet case assembly is assembled, the back portion edge of the outer back portion periphery being devoid of connection to the bezel edge of the outer bezel periphery when the tablet case assembly is assembled, the liner being sandwiched between the back portion and the bezel when the tablet case assembly is assembled.

7. A tablet case assembly as set forth in claim 6 wherein the recess is a first recess and the liner further includes a second recess, the first recess being located in the front liner face and the second recess being located in the rear liner face, the second recess being shaped and configured to receive the back portion.

8. A tablet case assembly as set forth in claim 6 wherein the bezel includes a plurality of bezel protrusions and the back portion includes a plurality of back portion protrusions, the bezel protrusions extending from the rear bezel face and the back portion protrusions extending from the front back portion face, the liner including a plurality of through-openings extending from the front liner face to the rear liner face, wherein one of the bezel protrusions and one of the back portion protrusion is located within each through-opening when the tablet case assembly is assembled.

9. A tablet case assembly as set forth in claim 8 wherein each of the bezel protrusions and each of the back portion protrusions are configured to receive a fastener.

10. A tablet case assembly as set forth in claim 6 wherein the liner has a liner hardness, the bezel has a bezel hardness and the back portion has a back portion hardness, the liner hardness being less than the bezel hardness, the liner hardness being less than the back portion hardness.

11. A tablet case assembly as set forth in claim 10 wherein the liner hardness has a Shore durometer measurement of at least 40 (A) and no greater than 100 (A).

12. A tablet case assembly as set forth in claim 11 wherein the liner hardness has a Shore durometer measurement of at least 55 (A) and no greater than 85 (A).

13. A tablet case assembly as set forth in claim 6 wherein the back portion further includes a plurality of mounting holes, the mounting holes being shaped and configured to enable the tablet case assembly to be mounted to a docking station when the tablet case assembly is assembled.

14. A tablet case assembly as set forth in claim 6 wherein the back portion edge of the outer back portion periphery is spaced from the bezel edge of the outer bezel periphery when the tablet case assembly is assembled.
